(19) United States
(12) Patent Application Publication
(10) Pub. No.: US 2012/0032216 A1
(43) Pub. Date: Feb. 9, 2012

(54) Light Emitting Diode Package Structure

(75) Inventors: Chao-Hsien Dong, New Taipei City (TW); Chien-Chang Pei, New Taipei City (TW)

(73) Assignees: EVERLIGHT ELECTRONICS CO., LTD., New Taipei City (TW); EVERLIGHT YI-GUANG TECHNOLOGY (SHANGHAI) LTD., Shanghai (CN)

(21) Appl. No.: 13/107,872

(22) Filed: May 13, 2011

(30) Foreign Application Priority Data
Aug. 5, 2010 (TW) 099126119

(51) Int. Cl. H01L 33/58

(52) U.S. Cl. 257/98; 257/E33.067

(57) ABSTRACT

Embodiments of a light emitting diode (LED) package structure are provided. In one aspect, an LED package structure includes a base, at least one LED chip, a blocking plate, and a transparent cover plate. The LED chip is disposed on and electrically coupled to the base. The blocking plate is disposed on the base and surrounds the LED chip. The blocking plate has an opening for exposing the LED chip. The blocking plate comprises a light-absorbing material that is opaque. The transparent cover plate is disposed on the blocking plate and covers the opening of the blocking plate.

### CROSS-REFERENCE TO RELATED APPLICATIONS

This application claims priority to Taiwan Patent Application No. 099126119, entitled “Light Emitting Diode Package Structure”, filed on Aug. 5, 2010, which is herein incorporated in its entirety by reference.

### BACKGROUND

1. Technical Field

The present disclosure relates to a light emitting diode (LED) package structure. More particularly, the present disclosure relates to an LED package structure with reduced stray light.

2. Description of Related Art

LEDs generally offer a number of advantageous characteristics such as fast response, compact size, low power consumption, low environmental pollution, high reliability, ease of mass production, etc. As a result LEDs are employed in a wide variety of applications including vehicle headlights, illumination fixtures, bulletin boards, traffic signal lights, mobile phones, and so on.

In operation LED chips generate heat. In the even that such heat accumulates in the LED chip and is not removed in a timely fashion, such heat may result in reduced efficiency in light emission or even damage to the LED chip. Therefore, common designs of LED lighting fixtures usually provide relatively large space to accommodate heat dissipating components at the expense of providing less space to accommodate optical components. With the size of optical components constrained by a relatively small space, the optical components may not collimate all the light emitted by the LED chip, resulting in the LED chip appearing to be a large illumination area with more stray light.

### SUMMARY

The present disclosure provides an LED package structure that has a small illumination area with less stray light.

In one aspect, an LED package structure may comprise a base, at least one LED chip, a blocking plate, and a transparent cover plate. The at least one LED chip is disposed on and electrically coupled to the base. The blocking plate is disposed on the base and surrounds the at least one LED chip. The blocking plate has an opening that exposes the at least one LED chip. The blocking plate comprises an opaque light-absorbing material. The transparent cover plate is disposed on the blocking plate and covers the opening of the blocking plate.

In one embodiment, the blocking plate has an inner sidewall and a first upper surface, and the at least one LED chip has a second upper surface and a side farthest from the inner sidewall of the blocking plate. The inner sidewall and the first upper surface of the blocking plate form a first vertex. The side and the second upper surface of the at least one LED chip form a second vertex. A straight line connecting the first vertex and the second vertex and the second upper surface form an included angle that is no greater than 30°.

In another embodiment, the blocking plate has an inner sidewall and the at least one LED chip has a side farthest from the inner sidewall of the blocking plate. An interval distance between the inner sidewall of the blocking plate and the side of the at least one LED chip farthest from the inner sidewall of the blocking plate is D. A height difference between the blocking plate and the at least one LED chip is T. A ratio of the height difference T to the interval distance D is no greater than tan 30°.

In another aspect, an LED package structure may comprise a carrier having a recess, at least one LED chip, and a cover plate. The at least one LED chip is received in the recess of the carrier and electrically coupled to the carrier. The cover plate is disposed on the carrier and covers the recess of the carrier. The cover plate has a transparent region and an opaque region surrounding the transparent region such that light generated by the at least one LED chip emits out of the transparent region.

In one embodiment, the opaque region has an inner sidewall and a first upper surface, and the at least one LED chip has a second upper surface and a side farthest from the inner sidewall of the opaque region. The inner sidewall and the first upper surface of the opaque region form a first vertex. The side and the second upper surface of the at least one LED chip form a second vertex. A straight line connecting the first vertex and the second vertex and the second upper surface form an included angle that is no greater than 20°.

In another embodiment, the opaque region has an inner sidewall, and the at least one LED chip has a side farthest from the inner sidewall of the opaque region. An interval distance between the inner sidewall of the opaque region and the side of the at least one LED chip farthest from the inner sidewall of the opaque region is D. A height difference between the cover plate and the at least one LED chip is T. A ratio of the height difference T to the interval distance D is no greater than tan 20°.

In another embodiment, the cover plate comprises a transparent plate and an opaque structure. The transparent plate is disposed on the carrier and covers the recess of the carrier. The opaque structure is disposed on the transparent plate and within the opaque region of the cover plate. The opaque structure has an opening exposing a portion of the transparent plate that is within the transparent region of the cover plate.

In still another embodiment, the cover plate comprises a transparent plate and an opaque structure. The transparent plate is disposed on the carrier and covers the recess of the carrier. The opaque structure is disposed between the transparent plate and the carrier, and is also disposed within the opaque region. The opaque structure has an opening corresponding to the recess of the carrier and a portion of the transparent plate that is within the transparent region of the cover plate.

In yet another embodiment, the opaque region covers at least partially a sidewall of the carrier.

In a further embodiment, the carrier comprises a base and a blocking plate. The at least one LED chip is disposed on the base and electrically coupled to the base. The blocking plate is disposed on the base and has an opening exposing the at least one LED chip. The opening of the blocking plate and the base form the recess. The blocking plate comprises an opaque light-absorbing material. The at least one LED chip is disposed in the opening. The cover plate is disposed on the blocking plate and covers the opening of the blocking plate.

In a further aspect, an LED package structure may comprise a carrier having a recess, at least one LED chip, a transparent cover plate, and a light-absorbing layer. The at least one LED chip is received in the recess of the carrier and electrically coupled to the carrier. The transparent cover plate is disposed on the carrier and covers the recess of the carrier. The light-absorbing layer is disposed on the transparent cover plate and has an opening such that at least a portion of light generated by the at least one LED chip emits through the transparent cover plate and the opening of the light-absorbing layer.

In one embodiment, the light-absorbing layer has an inner sidewall and a first upper surface, and the at least one LED chip has a second upper surface and a side farthest from the inner sidewall of the light-absorbing layer. The inner sidewall and the first upper surface of the light-absorbing layer form a first vertex. The side and the second upper surface of the at least one LED chip form a second vertex. A straight line connecting the first vertex and the second vertex and the second upper surface form an included angle that is no greater than 30°.

In another embodiment, the light-absorbing layer has an inner sidewall, and the at least one LED chip has a side farthest from the inner sidewall of the light-absorbing layer. An interval distance between the inner sidewall of the light-absorbing layer and the side of the at least one LED chip farthest from the inner sidewall of the light-absorbing layer is D. A height difference between the transparent cover plate and the at least one LED chip is T. A ratio of the height difference T to the interval distance D is no greater than tan 30°.

In one embodiment, the light-absorbing layer has an inner sidewall and a first upper surface, and the at least one LED chip has a second upper surface and a side farthest from the inner sidewall of the light-absorbing layer. The inner sidewall and the first upper surface of the light-absorbing layer form a first vertex. The side and the second upper surface of the at least one LED chip form a second vertex. A straight line connecting the first vertex and the second vertex and the second upper surface form an included angle that is no greater than 20°.

In another embodiment, the light-absorbing layer has an inner sidewall, and the at least one LED chip has a side farthest from the inner sidewall of the light-absorbing layer. An interval distance between the inner sidewall of the light-absorbing layer and the side of the at least one LED chip farthest from the inner sidewall of the light-absorbing layer is D. A height difference between the transparent cover plate and the at least one LED chip is T. A ratio of the height difference T to the interval distance D is no greater than tan 20°.

In one embodiment, the light-absorbing layer has an inner sidewall and a first upper surface, and the at least one LED chip has a second upper surface and a side farthest from the inner sidewall of the light-absorbing layer. The inner sidewall and the first upper surface of the light-absorbing layer form a first vertex. The side and the second upper surface of the at least one LED chip form a second vertex. A straight line connecting the first vertex and the second vertex and the second upper surface form an included angle that is no greater than 18°.

In another embodiment, the light-absorbing layer has an inner sidewall, and the at least one LED chip has a side farthest from the inner sidewall of the light-absorbing layer. An interval distance between the inner sidewall of the light-absorbing layer and the side of the at least one LED chip farthest from the inner sidewall of the light-absorbing layer is D. A height difference between the transparent cover plate and the at least one LED chip is T. A ratio of the height difference T to the interval distance D is no greater than tan 18°.

In one embodiment, the light-absorbing layer covers at least partially a sidewall of the transparent cover plate.

In one embodiment, the light-absorbing layer covers at least partially a sidewall of the transparent cover plate and a sidewall of the carrier.

In one embodiment, the carrier comprises a base and a blocking plate. The at least one LED chip is disposed on the base and electrically coupled to the base. The blocking plate is disposed on the base and has an opening exposing the at least one LED chip. The opening of the blocking plate and the base form the recess. The blocking plate comprises an opaque light-absorbing material. The at least one LED chip is disposed in the opening. The transparent cover plate is disposed on the blocking plate and covers the opening of the blocking plate.

These and other features, aspects, and advantages of the present disclosure will be explained below with reference to the following figures. It is to be understood that both the foregoing general description and the following detailed description are by examples, and are intended to provide further explanation of the present disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A illustrates an LED package structure in accordance with an embodiment of the present disclosure.

FIG. 1B illustrates a vertical view of the LED package structure of FIG. 1A.

FIG. 1C illustrates a cross-sectional view of the LED package structure of FIG. 1B along the line A-A.

FIG. 2A illustrates a variation of the LED package structure of FIG. 1A.

FIG. 2B illustrates a vertical view of the LED package structure of FIG. 2A.

FIG. 2C illustrates a cross-sectional view of the LED package structure of FIG. 2B along the line A-A.

FIG. 3A illustrates an LED package structure in accordance with another embodiment of the present disclosure.

FIG. 3B illustrates a vertical view of the LED package structure of FIG. 3A.

FIG. 3C illustrates a cross-sectional view of the LED package structure of FIG. 3B along the line A-A.

FIG. 4A illustrates a variation of the LED package structure of FIG. 3A.

FIG. 4B illustrates a vertical view of the LED package structure of FIG. 4A.

FIG. 4C illustrates a cross-sectional view of the LED package structure of FIG. 4B along the line A-A.

### DESCRIPTION OF PREFERRED EMBODIMENTS

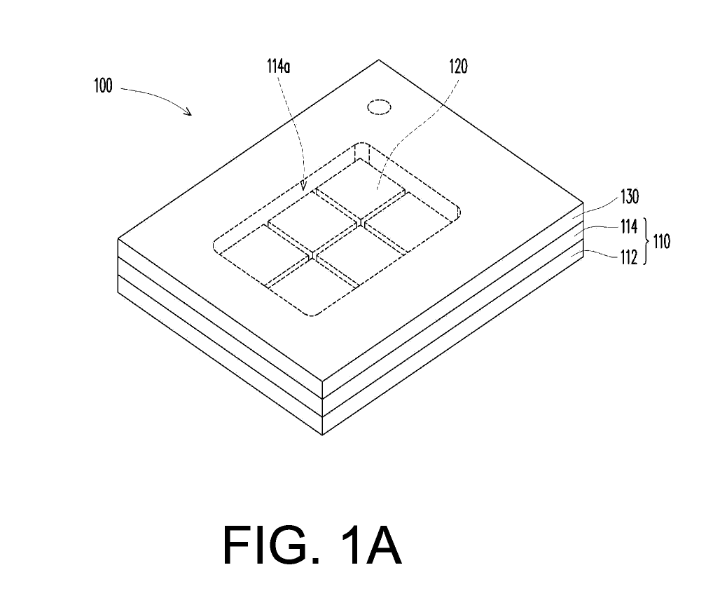

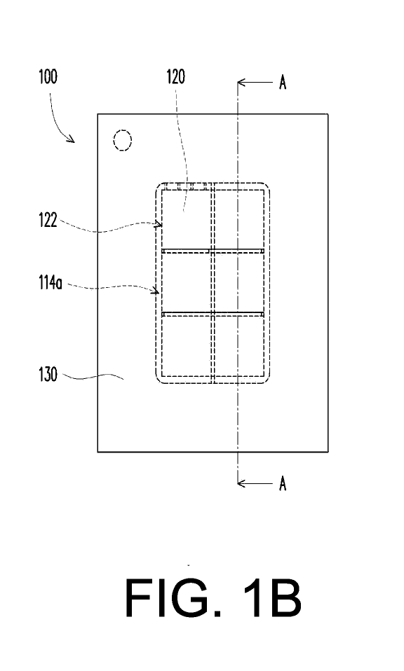

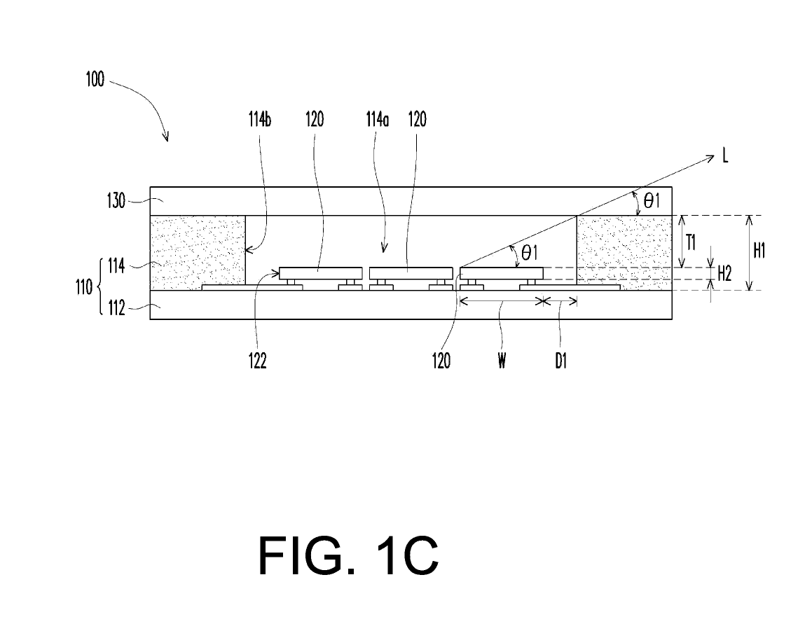

FIG. 1A illustrates an LED package structure in accordance with an embodiment of the present disclosure. FIG. 1B illustrates a vertical view of the LED package structure of FIG. 1A. FIG. 1C illustrates a cross-sectional view of the LED package structure of FIG. 1B along the line A-A.

Referring to FIGS. 1A, 1B and 1C, the LED package structure 100 comprises a carrier 110, a plurality of LED chips 120, and a transparent cover plate 130.

The carrier 110 comprises a base 112 and a blocking plate 114. The blocking plate 114 is disposed on the base 112 and has an opening 114a which exposes at least a portion of the base 112. The material of the blocking plate 114 comprises a light-absorbing material that is opaque such as, for example, a black or dark ceramic material or light-absorbing layer. The material of the base 112 may be, for example, ceramic, glass, silicon or metal. In one embodiment, the base 112 and the blocking plate 114 may be a monolithic structure formed as one piece.

The plurality of LED chips 120 are flip chip bonded to, as well as electrically coupled to, the base 112, and are located on a portion of the base 112 that is exposed by the opening 114a of the blocking plate 114. The blocking plate 114 surrounds the plurality of LED chips 120 and, relative to an optical axis of the LED chips 120, a primary surface of the blocking plate 114 may be perpendicular or otherwise angled. In one embodiment, as shown in FIG. 1C and using the right-most LED chip 120 as a representative of the other LED chips 120, given a thickness of the blocking plate 114 being H1, a thickness of the right-most LED chip 120 being H2, a distance, or height difference, between a surface of the blocking plate 114 that faces away from the base 112 and a surface of the right-most LED chip 120 that faces away from the base 112 being T1, a width of the right-most LED chip 120 being W, and a distance between a side of the right-most LED chip 120 closest to the blocking plate 114 and a side of the blocking plate 114 closest to the right-most LED chip 120 being D1, then a relationship among these parameters can be expressed as T1/(W+D1)≦tan θ1. In particular, the angle θ1 denotes the angle between the light ray L emitted by the LED chip 120 out of the opening 114 (i.e., θ1 is the angle between the light ray L emitted from the left-most portion of the right-most LED chip 120 and the top surface of the right-most LED chip 120, and θ1 is also the angle between the light ray L emitted from the left-most portion of the right-most LED chip 120 and the top surface of the blocking plate 114). In one embodiment, T1/(W+D1)≦tan 30°. In another embodiment, T1/(W+D1)≦tan 20°. In an alternative embodiment and preferably, T1/(W+D1)≦tan 18°. The transparent cover plate 130 is disposed on the blocking plate 114, located above the plurality of LED chips 120, and covers the opening 114a. The material of the transparent cover plate 130 may comprise glass or any other suitable transparent material.

Given that the LED chips 120 are flip chip bonded to the base 112, in one embodiment the opening 114a may be sized and shaped such that the inner sidewalls 114b of the opening 114a may be as close to the sides 122 of the LED chips 120 as possible.

Noticeably, by defining a height difference of between the blocking plate 114 and an LED chip 120 being T1, the width of the LED chip 120 being W, and an interval distance between one of the LED chips 120 and the blocking plate 114 being D1, the angle θ1 at which the light ray L is emitted from the LED chip 120 out of the opening 114a can be derived. That is, through the equation T1/(W+D1)≦tan 30° (or tan 20° or tan 18°), the angle θ1 can be determined to be 30° (or 20° or 18°).

In other words, the LED chip 120 has two opposing sides: a first side (e.g., the right side) and a second side (e.g., the left side) where the first side is closer to the blocking plate 114 (e.g., the inner sidewall on the right) than the second side. With a height difference (e.g., T1) between the blocking plate 114 and the LED chip 120 and an interval distance (e.g., D1) between the blocking pate 114 (e.g., the inner sidewall on the right) and the first side (e.g., the right side), a ratio of the height difference to the interval distance is no greater than a tangent function of 30 degrees, tan 30°.

In one embodiment, the blocking plate 114 has an inner sidewall (e.g., the inner sidewall on the right) and a first upper surface. The LED chip 120 has a second upper surface and a side (e.g., the left side) that is farthest from the inner sidewall of the blocking plate 114. Between the inner sidewall and the first upper surface of the blocking plate 114 there is a first vertex (e.g., a corner vertex), and between the side and the second upper surface of the LED chip 120 there is a second vertex (e.g., a corner vertex). Between a straight line connecting the first vertex and the second vertex (e.g., the light ray L) and the second upper surface there is an included angle (e.g., the angle θ1) that is no greater than 30°.

In another embodiment, the blocking plate 114 has an inner sidewall (e.g., the inner sidewall on the right), and the LED chip 120 has a side (e.g., the left side) that is farthest from the inner sidewall of the blocking plate 114. Between the inner sidewall of the blocking plate 114 and the side of the LED chip 120 there is an interval distance (e.g., D1), and between the blocking plate 114 and the LED chip 120 there is a height difference (e.g., T1). A ratio of such height difference and interval distance is no greater than the tangent function of 30 degrees, tan 30°.

Moreover, with the inner sidewalls 114b of the opening 114a as close to the sides 122 of the LED chips 120 as possible according to one embodiment, the inner sidewalls 114b can be used to block large-angle stray light emitted from the sides 122 of the LED chips 120. The blocking plate 114 can absorb a majority of incident light, attenuate the strength of reflection of the incident light, and reduce the probability of reflection of the incident light, thereby reducing the illumination area of the LED package structure 100 and lowering the effect of surface light source. Additionally, the height of the blocking plate 114 and the size of the opening 114a may be flexibly designed to adjust and control the light emitting field or pattern of the LED chips 120.

Furthermore, with the inner sidewalls 114b of the opening 114a as close to the sides 122 of the LED chips 120 as possible according to one embodiment, the inner sidewalls 114b in turn limit the amount of area spreadable with phosphorus and thereby limit the illumination area of the LED package structure.

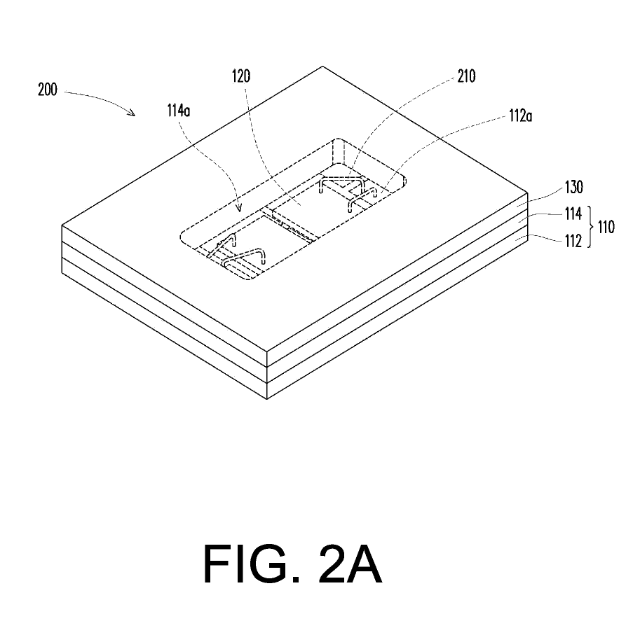

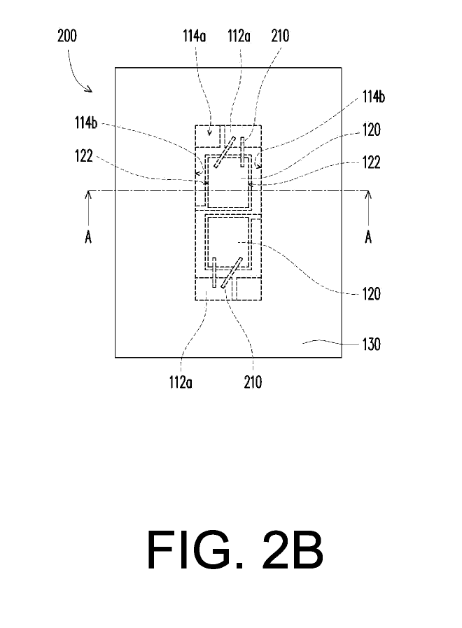

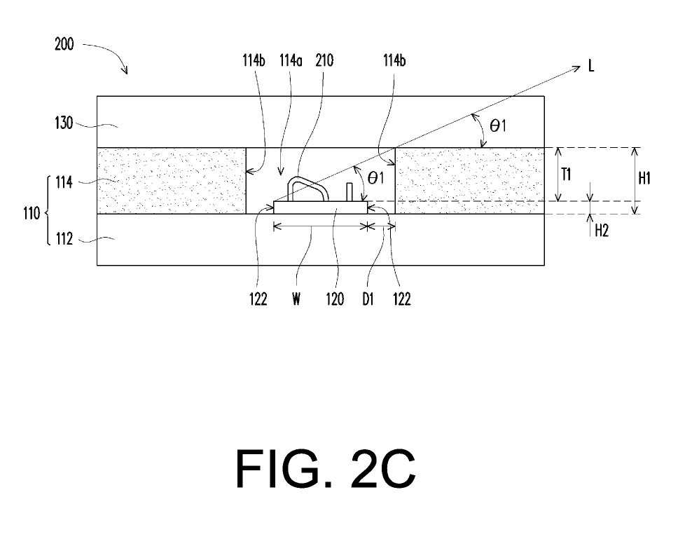

FIG. 2A illustrates a variation of the LED package structure of FIG. 1A. FIG. 2B illustrates a vertical view of the LED package structure of FIG. 2A. FIG. 2C illustrates a cross-sectional view of the LED package structure of FIG. 2B along the line A-A.

Referring to FIGS. 2A, 2B and 2C, the LED package structure 200 in accordance with one embodiment is similar to the LED package structure 100 of FIG. 1A with the main difference being that the LED chips 120 of the LED package structure 200 are wire bonded to the base 112. More specifically, the LED package structure 200 also comprises a plurality of conductive wires 210 that provide electrical conductive paths between the LED chips 120 and the base 112. In one embodiment, the conductive wires 210 are gold wires.

In one embodiment, as it is necessary to reserve a portion of the space of the opening 114a for the purpose of wire bonding, a portion of the inner sidewalls 114b of the opening 114a can be as close to the sides 122 of the LED chips as possible. In one embodiment, the LED chips 120 and the direction of wire bonding are so arranged such that the portion of the inner sidewalls 114b of the opening 114a that can be as close to the sides 122 of the LED chips 120 as possible is maximized.

In one embodiment, the LED chips 120 are arranged in a row (or a line or an array), with multiple conductive wires 210 connected between respective outer sides of the LED chips 120 and conductive lines 112b of the base 112. As such, two opposing inner sidewalls 114b of the opening 114a can be as close to the sides 122 of the LED chips 120 as possible.

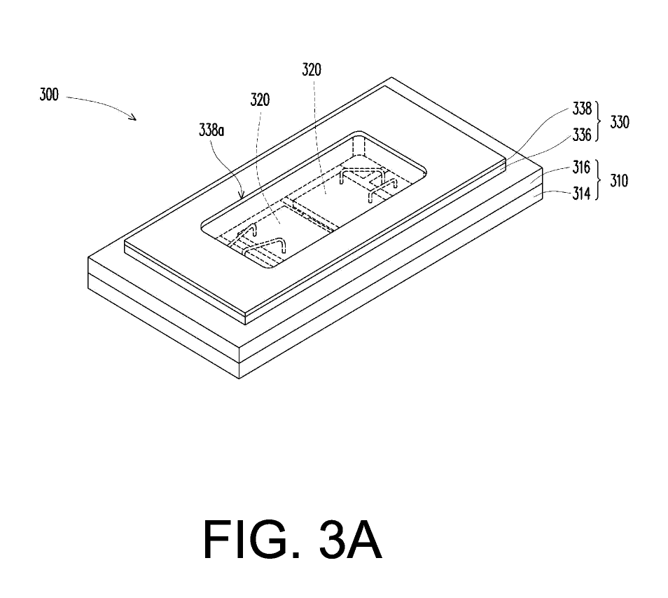

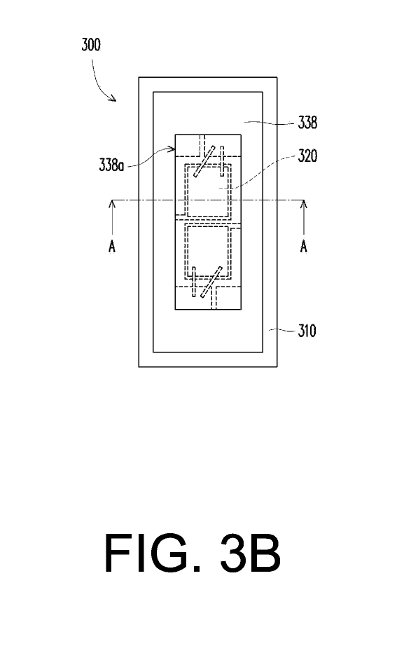

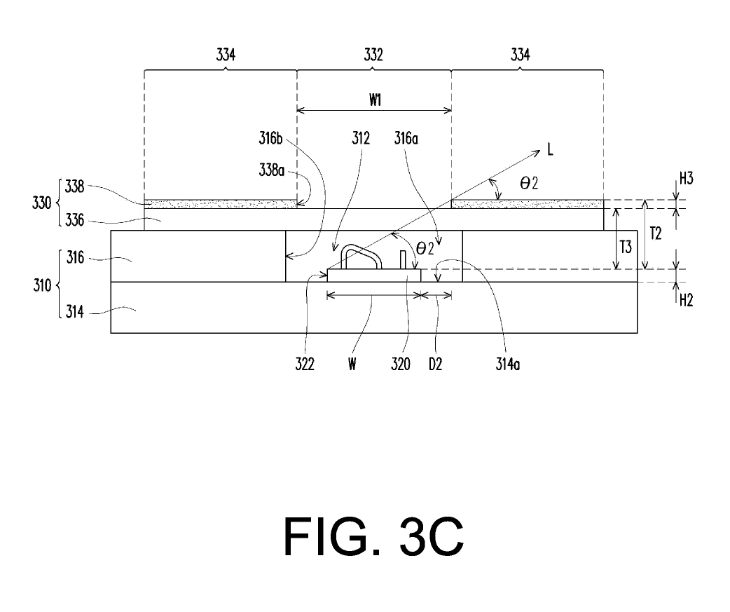

FIG. 3A illustrates an LED package structure in accordance with another embodiment of the present disclosure. FIG. 3B illustrates a vertical view of the LED package structure of FIG. 3A. FIG. 3C illustrates a cross-sectional view of the LED package structure of FIG. 3B along the line A-A.

Referring to FIGS. 3A, 3B and 3C, the LED package structure 300 comprises a carrier 310, a plurality of LED chips 320, and a cover plate 330. The carrier 310 has a recess 312. More specifically, in one embodiment, the carrier 310 comprises a base 314 and a blocking plate 316. The blocking plate 316 is disposed on the base 314 and has an opening 316a that exposes a partial surface 314a of the base 314. The inner sidewalls 316b of the opening 316a and the partial surface 314a of the base 314 form the recess 312. The base 314 and the blocking plate 316 are each made of an opaque material such as, for example, ceramic, silicon or metal. Additionally, the base 314 and the blocking plate 316 may be a monolithic structure formed as one piece.

The LED chips 320 are disposed in the recess 312 and electrically coupled to the carrier 310. The cover plate 330 is disposed on the carrier 310, located over the LED chips 320, and covers the recess 312. The cover plate 330 comprises a transparent region 332 and an opaque region 334 surrounding the transparent region 332. The transparent region 332 is disposed above the LED chips 320. Noticeably, in one embodiment, a ratio between the width W1 of the transparent region 332 and the width W of the LED chips 320 represents a ratio between the width W1 of the transparent region 332 and the width W of the LED chips 320 in the same cross section (e.g., the cross section along the line A-A in FIG. 3B). Additionally, if the cross section intersects more than one of the LED chips 320, then the ratio is between the width W1 of the transparent region 332 and the sum of the widths W of all the LED chips 320 that intersect the cross section.

In one embodiment, the cover plate 330 comprises a transparent plate 336 and an opaque structure 338. The transparent plate 336 is disposed on the carrier 310, located over the LED chips 320, and covers the recess 312. The opaque structure 338 is disposed on the transparent plate 336 and is within the opaque region 334. The opaque structure 338 has an opening 338a that exposes a portion of the transparent plate 336 that is within the transparent region 332. The opaque structure 338 may be, for example, a black ink layer or a light-absorbing layer. Relative to an optical axis of the LED chips 120, a primary surface of the opaque structure 338 may be perpendicular or otherwise angled. Moreover, the opaque structure 338 may be disposed between the transparent plate 336 and the blocking plate 316. The opaque structure 338 may be disposed between the transparent plate 336 and the carrier 310, and may be within the opaque region 334. The opaque structure 338 may have an opening that corresponds to the recess 312 and the portion of the transparent plate 336 that is within the transparent region 332.

Referring to FIG. 3C, in one embodiment, the opaque structure 338 has a thickness of H3, the LED chips 320 in general have a thickness of H2, and a surface of a side of the transparent plate 336 of the cover plate 330 facing away from the carrier 310 has a height of T3 as measured from a surface of a side of the LED chips 320 facing away from the carrier 310. A surface of a side of the opaque structure 338 of the cover plate 330 facing away from the carrier 310 has a height of T2 as measured from a surface of a side of the LED chips 320 facing away from the carrier 310 (equal to the sum of T3 and H3). The LED chips 320 each has a width of W. A horizontal interval distance between a side surface of an LED chip 320 near the opaque region 334 and a side surface of the opaque region 334 near the LED chip 320 is D2 (in other words, the horizontal interval distance between a side surface of an LED chip 320 near the opaque structure 338 and a side surface of the opaque structure 338 near the LED chip 320 is D2). A relationship among these parameters can be expressed as T2/(W+D2)≦tan θ2≦T2/W. In one embodiment, the value of D2 may be 0. The angle θ2 denotes the angle between the light ray L emitted by the LED chip 320 out of the opening 316a (i.e., θ2 is the angle between the light ray L emitted from the left-most portion of the LED chip 320 and the top surface of the LED chip 320, and θ2 is also the angle between the light ray L emitted from the left-most portion of the LED chip 320 and the top surface of the opaque structure 338). In one embodiment, preferably the angle θ2 is 30°.

By defining a height difference of between the cover plate 330 and an LED chip 320 being T2, the width of the LED chip 320 being W, and an interval distance between the LED chip 320 and the opaque region 334 being D2 (or equivalently an interval distance between the LED chip 320 and the opaque structure 338 being D2), the angle θ2 at which the light ray L is emitted from the LED chip 320 out of the opening 316a can be derived. That is, through the equation T2/(W+D2)≦tan θ2, the angle θ2 can be determined, for example, to be 20°.

In other words, the LED chip 320 has two opposing sides: a first side (e.g., the right side) and a second side (e.g., the left side) where the first side is closer to the opaque region 334 (e.g., the inner sidewall on the right) than the second side. With a height difference (e.g., T2) between the cover plate 330 and the LED chip 320 and an interval distance (e.g., D2) between the opaque region 334 (e.g., the inner sidewall on the right) and the first side (e.g., the right side), a ratio of the height difference to the interval distance is no greater than a tangent function of 20 degrees, tan 20°.

In one embodiment, the opaque region 334 has an inner sidewall (e.g., the inner sidewall on the right) and a first upper surface. The LED chip 320 has a second upper surface and a side (e.g., the left side) that is farthest from the inner sidewall of the opaque region 334. Between the inner sidewall and the first upper surface of the opaque region 334 there is a first vertex (e.g., a corner vertex), and between the side and the second upper surface of the LED chip 320 there is a second vertex (e.g., a corner vertex). Between a straight line connecting the first vertex and the second vertex (e.g., the light ray L) and the second upper surface there is an included angle (e.g., the angle θ2) that is no greater than 20°.

In another embodiment, the opaque region 334 has an inner sidewall (e.g., the inner sidewall on the right), and the LED chip 320 has a side (e.g., the left side) that is farthest from the inner sidewall of the opaque region 334. Between the inner sidewall of the opaque region 334 and the side of the LED chip 320 there is an interval distance (e.g., D2), and between the cover plate 330 and the LED chip 320 there is a height difference (e.g., T2). A ratio of such height difference and interval distance is no greater than a tangent function of 20 degrees, tan 20°.

Noticeably, in one embodiment, the size of the transparent region 332 can be adjusted by adjusting the size of the opening 338a of the opaque structure 338 (width or area), so as to adjust the illumination area of the LED package structure 300. Accordingly, stray light emitted from the side 322 of the LED chip 320 can be minimized by reducing the size of the opening 338a of the opaque structure 338. The opaque structure 338 can absorb a majority of incident light, attenuate the strength of reflection of the incident light, and reduce the probability of reflection of the incident light, thereby reducing the light guide effect of the transparent plate 336 and lowering the effect of surface light source. Additionally, the height of the opaque region 334 and the size of the transparent region 332 may be flexibly designed to adjust and control the light emitting field or pattern of the LED chips 320.

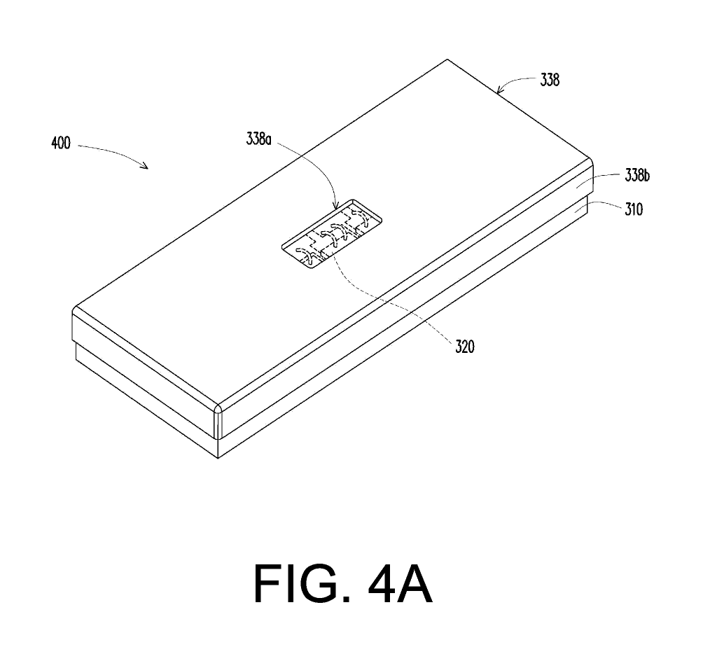

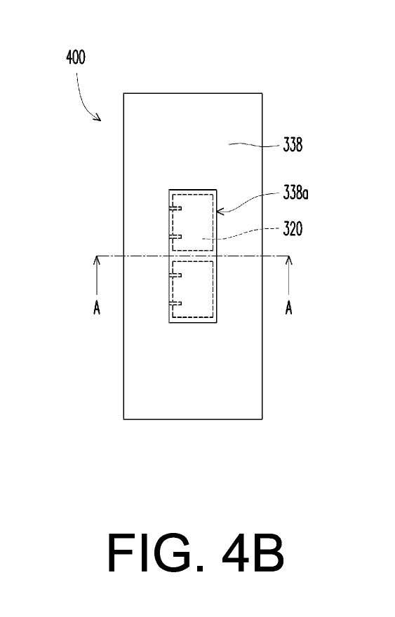

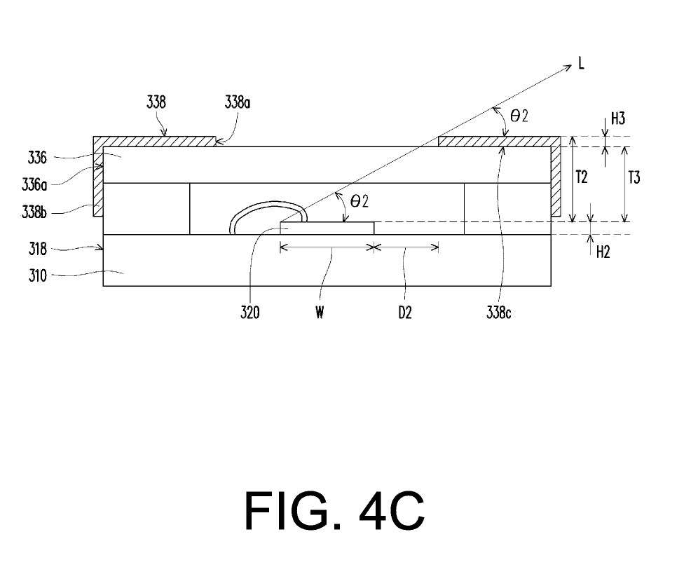

FIG. 4A illustrates a variation of the LED package structure of FIG. 3A. FIG. 4B illustrates a vertical view of the LED package structure of FIG. 4A. FIG. 4C illustrates a cross-sectional view of the LED package structure of FIG. 4B along the line A-A.

Referring to FIGS. 4A, 4B and 4C, the LED package structure 400 in accordance with one embodiment is similar to the LED package structure 300 of FIG. 3A with the main difference being that the opaque structure 338 of the LED package structure 400 further includes an extension 338b. The extension 338b may cover at least partially the outer sidewalls 336a and 318 of the transparent plate 336 and the carrier 310, respectively. The opaque structure 338 may be, for example, a metallic shell. The opaque structure 338 may be press fitted, glued or otherwise coupled to the transparent plate 336 and the carrier 310.

Noticeably, when the material of the opaque structure 338 is a material with good reflectivity (e.g., a metallic material), then the light blocked by the opaque structure 338 (e.g., light emitted by the LED chips 320) may be reflected a plurality of times between an inner surface 338c of the opaque structure 338 and the carrier 310 before being emitted out of the opening 338a. As a result, the amount of light emitted from the LED package structure 400 is increased. In one embodiment, regardless of whether the opaque structure 338 is made of a reflective material, a reflective layer structure may be provided between the opaque structure 338 and the transparent plate 336 and between the opaque structure 338 and the carrier 310.

In view of the above description, an LED package structure according to the present disclosure may include an opaque and light-absorbing blocking plate. Large-angle stray light emitted from the sides of the LED chips can be blocked by having the inner sidewalls of the opening of the blocking plate close to the sides of the LED chips. This reduces the illumination area of the LED package structure and lowers the effect of surface light source.

An LED package structure according to the present disclosure may further include a cover plate disposed on the carrier. The cover plate includes a transparent region and an opaque region surrounding the transparent region. The illumination area of the LED package structure can be reduced by reducing the size of the transparent region. Stray light emitted from the sides of the LED chips can also be reduced. As a result, the effect of surface light source is reduced accordingly.

Although some embodiments are disclosed above, they are not intended to limit the scope of the present disclosure. It will be apparent to those skilled in the art that various modifications and variations can be made to the disclosed embodiments of the present disclosure without departing from the scope or spirit of the present disclosure. In view of the foregoing, the scope of the present disclosure shall be defined by the following claims and their equivalents.

What is claimed is:

1. A light emitting diode (LED) package structure, comprising:
a base;
at least one LED chip disposed on and electrically coupled to the base;
a blocking plate disposed on the base and surrounding the at least one LED chip, the blocking plate having an opening that exposes the at least one LED chip, the blocking plate comprising an opaque light-absorbing material; and
a transparent cover plate, disposed on the blocking plate, that covers the opening of the blocking plate.

2. The LED package structure of claim 1, wherein the blocking plate has an inner sidewall and a first upper surface, and wherein the at least one LED chip has a second upper surface and a side farthest from the inner sidewall of the blocking plate, the inner sidewall and the first upper surface of the blocking plate forming a first vertex, the side and the second upper surface of the at least one LED chip forming a second vertex, a straight line connecting the first vertex and the second vertex and the second upper surface forming an included angle that is no greater than 30°.

3. The LED package structure of claim 1, wherein the blocking plate has an inner sidewall, and wherein the at least one LED chip has a side farthest from the inner sidewall of the blocking plate, an interval distance between the inner sidewall of the blocking plate and the side of the at least one LED chip farthest from the inner sidewall of the blocking plate being D, a height difference between the blocking plate and the at least one LED chip being T, a ratio of the height difference T to the interval distance D being no greater than tan 30°.

4. A light emitting diode (LED) package structure, comprising:
a carrier, the carrier having a recess;
at least one LED chip received in the recess of the carrier and electrically coupled to the carrier; and
a cover plate disposed on the carrier and covering the recess of the carrier, the cover plate having a transparent region and an opaque region surrounding the transparent region such that light generated by the at least one LED chip emits out of the transparent region.

5. The LED package structure of claim 4, wherein the opaque region has an inner sidewall and a first upper surface, and wherein the at least one LED chip has a second upper surface and a side farthest from the inner sidewall of the opaque region, the inner sidewall and the first upper surface of the opaque region forming a first vertex, the side and the second upper surface of the at least one LED chip forming a second vertex, a straight line connecting the first vertex and the second vertex and the second upper surface forming an included angle that is no greater than 20°.

6. The LED package structure of claim 4, wherein the opaque region has an inner sidewall, and wherein the at least one LED chip has a side farthest from the inner sidewall of the opaque region, an interval distance between the inner sidewall of the opaque region and the side of the at least one LED chip farthest from the inner sidewall of the opaque region being D, a height difference between the cover plate and the at least one LED chip being T, a ratio of the height difference T to the interval distance D being no greater than tan 20°.

7. The LED package structure of claim 4, wherein the cover plate comprises:
a transparent plate disposed on the carrier and covering the recess of the carrier; and
an opaque structure disposed on the transparent plate and within the opaque region of the cover plate, the opaque structure having an opening exposing a portion of the transparent plate that is within the transparent region of the cover plate.

8. The LED package structure of claim 4, wherein the cover plate comprises:
a transparent plate disposed on the carrier and covering the recess of the carrier; and
an opaque structure disposed between the transparent plate and the carrier, the opaque structure also disposed within the opaque region, the opaque structure having an opening corresponding to the recess of the carrier and a portion of the transparent plate that is within the transparent region of the cover plate.

9. The LED package structure of claim 4, wherein the opaque region covers at least partially a sidewall of the carrier.

10. The LED package structure of claim 4, wherein the carrier comprises:
a base, the at least one LED chip disposed on the base and electrically coupled to the base; and
a blocking plate disposed on the base and having an opening exposing the at least one LED chip, the opening of the blocking plate and the base forming the recess, the blocking plate comprising an opaque light-absorbing material, the at least one LED chip disposed in the opening, the cover plate disposed on the blocking plate and covering the opening of the blocking plate.

11. A light emitting diode (LED) package structure, comprising:
a carrier, the carrier having a recess;
at least one LED chip received in the recess of the carrier and electrically coupled to the carrier;
a transparent cover plate disposed on the carrier and covering the recess of the carrier; and
a light-absorbing layer disposed on the transparent cover plate and having an opening such that at least a portion of light generated by the at least one LED chip emits through the transparent cover plate and the opening of the light-absorbing layer.

12. The LED package structure of claim 11, wherein the light-absorbing layer has an inner sidewall and a first upper surface, and wherein the at least one LED chip has a second upper surface and a side farthest from the inner sidewall of the light-absorbing layer, the inner sidewall and the first upper surface of the light-absorbing layer forming a first vertex, the side and the second upper surface of the at least one LED chip forming a second vertex, a straight line connecting the first vertex and the second vertex and the second upper surface forming an included angle that is no greater than 30°.

13. The LED package structure of claim 11, wherein the light-absorbing layer has an inner sidewall, and wherein the at least one LED chip has a side farthest from the inner sidewall of the light-absorbing layer, an interval distance between the inner sidewall of the light-absorbing layer and the side of the at least one LED chip farthest from the inner sidewall of the light-absorbing layer being D, a height difference between the transparent cover plate and the at least one LED chip being T, a ratio of the height difference T to the interval distance D being no greater than tan 30°.

14. The LED package structure of claim 11, wherein the light-absorbing layer has an inner sidewall and a first upper surface, and wherein the at least one LED chip has a second upper surface and a side farthest from the inner sidewall of the light-absorbing layer, the inner sidewall and the first upper surface of the light-absorbing layer forming a first vertex, the side and the second upper surface of the at least one LED chip forming a second vertex, a straight line connecting the first vertex and the second vertex and the second upper surface forming an included angle that is no greater than 20°.

15. The LED package structure of claim 11, wherein the light-absorbing layer has an inner sidewall, and wherein the at least one LED chip has a side farthest from the inner sidewall of the light-absorbing layer, an interval distance between the inner sidewall of the light-absorbing layer and the side of the at least one LED chip farthest from the inner sidewall of the light-absorbing layer being D, a height difference between the transparent cover plate and the at least one LED chip being T, a ratio of the height difference T to the interval distance D being no greater than tan 20°.

16. The LED package structure of claim 11, wherein the light-absorbing layer has an inner sidewall and a first upper surface, and wherein the at least one LED chip has a second upper surface and a side farthest from the inner sidewall of the light-absorbing layer, the inner sidewall and the first upper surface of the light-absorbing layer forming a first vertex, the side and the second upper surface of the at least one LED chip forming a second vertex, a straight line connecting the first vertex and the second vertex and the second upper surface forming an included angle that is no greater than 18°.

17. The LED package structure of claim 11, wherein the light-absorbing layer has an inner sidewall, and wherein the at least one LED chip has a side farthest from the inner sidewall of the light-absorbing layer, an interval distance between the inner sidewall of the light-absorbing layer and the side of the at least one LED chip farthest from the inner sidewall of the light-absorbing layer being D, a height difference between the transparent cover plate and the at least one LED chip being T, a ratio of the height difference T to the interval distance D being no greater than tan 18°.

18. The LED package structure of claim 11, wherein the light-absorbing layer covers at least partially a sidewall of the transparent cover plate.

19. The LED package structure of claim 11, wherein the light-absorbing layer covers at least partially a sidewall of the transparent cover plate and a sidewall of the carrier.

20. The LED package structure of claim 11, wherein the carrier comprises:
a base, the at least one LED chip disposed on the base and electrically coupled to the base; and
a blocking plate disposed on the base and having an opening exposing the at least one LED chip, the opening of the blocking plate and the base forming the recess, the blocking plate comprising an opaque light-absorbing material, the at least one LED chip disposed in the opening, the transparent cover plate disposed on the blocking plate and covering the opening of the blocking plate.
